(19) United States
(12) Patent Application Publication
(10) Pub. No.: US 2008/0106251 A1
(43) Pub. Date: May 8, 2008

(54) DAYLIGHT-READABLE DIGITAL PANEL METER WITH AUTO-BRIGHTNESS ADJUSTING LED DISPLAY

(76) Inventors: Roy Manuel CABRAL, North Attleboro, MA (US); Joshua Clayton JOHNSTONE, North Attleboro, MA (US); Gary Charles PERRY, East Providence, RI (US)

Correspondence Address: Murata Power Solutions;c/o Keating & Bennett, LLP, 8180 Greensboro Drive, Suite 850, McLean, VA, 22102, US

(21) Appl. No.: 11/933,782

(22) Filed: Nov. 1, 2007

Related U.S. Application Data
(60) Provisional application No. 60/856,775, filed on Nov. 3, 2006.

(51) Int. Cl. G01R 11/57; H01L 27/15

(52) U.S. Cl. 324/114; 315/150

(57) ABSTRACT

A digital panel meter includes a light-emitting diode (LED) display that is sufficiently bright to be easily read in direct sunlight. The digital panel meter also includes an ambient light-sensing circuit which automatically and continuously adjusts the brightness of the LED display in order to provide adequate readability in ambient light conditions ranging from full sunlight to total darkness.

This application claims the benefit of U.S. Provisional Patent Application Ser. No. 60/856,775, filed on Nov. 3, 2006.

### BACKGROUND OF THE INVENTION

1. Field of the Invention

The present invention relates to light emitting diode (“LED”) digital panel meters. More specifically, the present invention relates to daylight-readable, auto-dimming LED digital panel meters.

2. Description of the Related Art

LED displays used in existing digital panel meters become “washed out” and hard-to-read when operated in direct sunlight. Previously, designers of digital instrumentation that had to be readable in broad daylight could only employ liquid crystal display (“LCD”) or vacuum florescent display (“VFD”) technologies.

However, in order to remain legible in low ambient light, LCDs require power-dissipating backlighting circuitry. Furthermore, LCDs suffer from relatively narrow viewing angles which restrict their use in many applications.

VFD-based instruments are expensive and require complex drive circuitry, rendering them cost-prohibitive for the majority of digital panel instrument applications. Additionally, due to their glass-based construction, LCD and VFD display technologies are both inherently less reliable than the epoxy encapsulated, solid-state LED displays employed in the preferred embodiments of the present invention.

The present inventors have previously attempted to achieve a daylight-readable digital panel meter by using glass filters that featured miniature built-in “venetian blinds.” The purpose of the “venetian blinds” was to provide directional shading from ambient sunlight from striking the face of the LED display. However, this technique required repositioning the digital panel meter as the sun traversed across the sky, a condition that is not practical in real-world applications.

The present inventors have also previously attempted to achieve a daylight-readable digital panel meter by using so-called “high intensity” LED displays. However, several problems were encountered. Many of the so-called “high intensity” LED displays were not readable in direct sunlight, i.e., the “high intensity” LED displays were not daylight readable.

Of the so-called “high intensity” LED displays that where daylight readable, driving the “high intensity” LED displays at the maximum rated currents dissipated excessive heat and power, which in turn caused temperatures inside the digital panel meter to increase such that the stability, the accuracy, and the long term reliability were negatively impacted. Further, these “high intensity” LED displays had the unexpected problem of being so bright that the LED displays were not readable indoors or at nighttime with out adjustment. That is, previous to the present invention, digital panel meters were not available that were readable in daylight, nighttime, and indoors without manual adjustments and that did not generate excessive heat and power.

Readily available commercial LED displays of the type used in existing digital panel meters are not offered with built-in ambient light sensors or a device to collect ambient light for sensing purposes.

### SUMMARY OF THE INVENTION

To overcome the problems described above, preferred embodiments of the present invention provide a daylight-readable digital panel meter having an auto-dimming LED display that detects incoming ambient light without detracting from the appearance of the LED display or increasing the daylight-readable digital panel meter's size in any dimension.

The digital panel meter includes a plurality of LED displays that is readable in direct sunlight without the need to use special filters or shading devices.

The LED displays can be a known seven segment LED, for example, or any other type of LED display.

The digital panel meter includes an “auto-dimming” feature that automatically and continuously adjusts the LED display's brightness to suit all lighting environments, ranging from full sunlight to total darkness. Without the automatic dimming function and under normal indoor lighting conditions, the super-bright LED display would be very difficult to read.

The digital panel meter preferably includes an LED display, operating electronics such as display drivers, signal conditioning electronics, which preferably includes an analog-to-digital converter (ADC) integrated circuit (IC), an ambient light sensor, and a reference circuit mounted to circuit board into the compact assembly.

All operating electrical power is preferably derived from a single, user-supplied +5V DC power supply. When operated in total darkness, current draw is preferably less than about 10 mA (0.05 Watt). At maximum brightness (i.e., in full sunlight) power consumption is preferably less than about 200 mA (1 Watt).

The digital panel meter preferably includes a hole drilled through the LED display's front viewing surface. The hole, which forms a light access aperture, extends completely through the body of the LED display and focuses ambient light directly onto the photosensitive surface of the ambient light sensor, which is located directly underneath the LED display on the circuit board.

Other features, elements, characteristics and advantages of the present invention will become more apparent from the following detailed description of preferred embodiments of the present invention with reference to the attached drawings.

### BRIEF DESCRIPTION OF THE DRAWINGS

FIG. 1 is a block diagram of a preferred embodiment of the present invention.

FIG. 2A is a circuit diagram of an auto-dimmer according to a preferred embodiment of the present invention.

FIG. 2B is circuit diagram of an ADC according to a preferred embodiment of the present invention.

FIG. 2C is a circuit diagram of an LED display according to a preferred embodiment of the present invention.

FIG. 3 is an exploded view of an LED display according to a preferred embodiment of the present invention.

FIG. 4 is a perspective view of an LED display according to a preferred embodiment of the present invention.

FIG. 5 is an exploded view of a digital panel meter according to a preferred embodiment of the present invention.

FIG. 6 is a perspective a digital panel meter according to a preferred embodiment of the present invention.

### DETAILED DESCRIPTION OF PREFERRED EMBODIMENTS

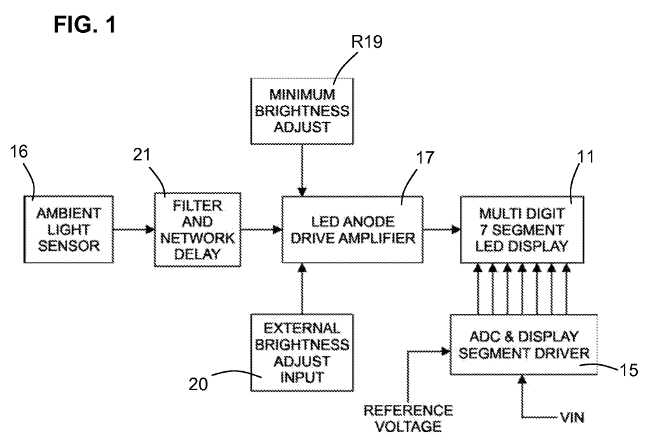

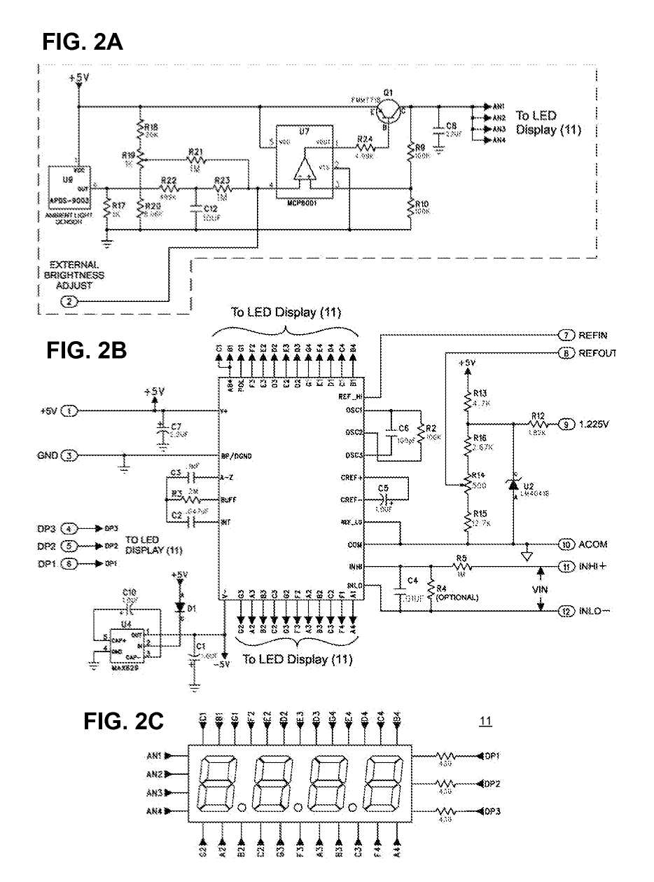

Preferred embodiments of the present invention will be described with reference to FIGS. 1-6. FIG. 1 shows a block diagram of a preferred embodiment of the present invention. An LED display 11 is controlled by the LED display driver 15, which is shown in FIG. 2B, and an LED anode driver amplifier 17, which is shown in FIG. 2A. The LED display driver 15 determines what is displayed by the LED display 11. A voltage VIN is inputted into the LED display driver 15 to determine what is displayed by the LED display 11. A reference voltage is also inputted into the LED display driver 15.

The LED anode driver amplifier 17 determines the brightness of the LED display 11. The brightness of the LED display 11 is determined by the minimum brightness adjuster R19, the external brightness adjust input 20, and the ambient light sensor 16. FIG. 2A is a detailed circuit diagram of the LED anode driver amplifier 17, the minimum brightness adjuster R19, the external brightness adjust input 20, and the ambient light sensor 16. The minimum brightness adjuster R19 determines the minimum brightness of the LED display 11. The external brightness adjust input 20 can set the LED display 11 to the maximum brightness or the minimum brightness, disabling the auto-dimming function of the ambient light sensor 16, or can manually set the LED display's brightness. The ambient light sensor 16 is connected to the LED anode drive amplifier 17 via the filter and network delay 21.

The LED display 11 preferably has a brightness of at least about 100 mcd (about 0.1 candela) when driven by at most 10 mA DC current. With this brightness, the digital panel meter 10 is daylight-readable, and with this driving current, the power dissipated by the LED display 11 is not unnecessarily high so that the stability, the accuracy, and the long term reliability of the digital panel meter 10 are not negatively impacted.

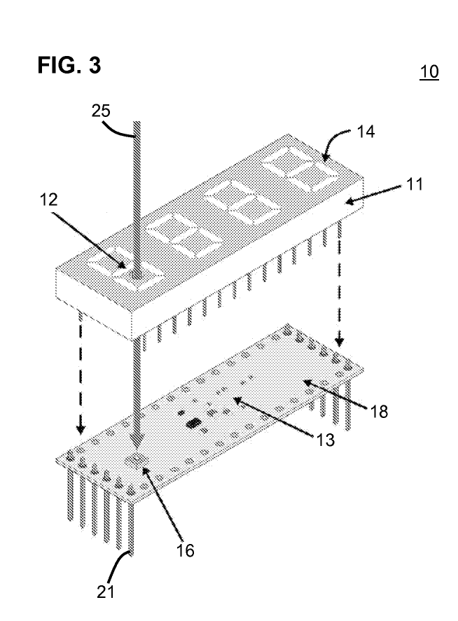

Except for LED display 11, all of the supporting electronic circuitry 13 shown in FIGS. 2A and 2B are preferably located on the circuit board 18, as shown in FIG. 3. Preferably, the circuit board 18 is a double-sided printed pc-board assembly. Any other suitable assembly can also be used for circuit board 18.

The circuit board 18 contains twelve input/output pins 21. The twelve pins 21, shown in FIGS. 3-6, connect external signals and control inputs to the support electronics 13 and the LED display 11 of the preferred embodiments of the present invention. The twelve pins 21 preferably include the following pin functions:

+5V and GND;

DP1, DP2 and DP3;

External Brightness Adjust;

INHI+ and INLO−;

ACOM;

1.225V; and

REFOUT and REFIN.

The function, nomenclature, and use of the twelve pins 21 are well known to those skilled in the art. It is also possible to use a different arrangement of pins 21 and to use pins 21 having different functions. For example, the pins 21 could be arranged along a single side of the circuit board 18 instead of arranged on opposing sides of the circuit board 18. It is also possible to use surface mount technology instead of the pins 21 used with through-hole technology.

FIG. 2A shows the auto-dimmer circuit according to a preferred embodiment of the present invention. The ambient light sensor's 16 output current varies in direct proportion to the intensity of the ambient light striking its photosensitive top surface. The output current of the ambient light sensor 16 is preferably continuous so that LED display is continuously adjusted. Preferably, the ambient light sensor 16 is an integrated circuit. However, any other suitable light sensor can be used. Preferably, the ambient light sensor 16 has the same or substantially the same response to the ambient light as the human eye's response to the ambient light, which ensures that the digital panel meter 10 is readable in daylight, nighttime, and indoors. The ambient light sensor preferably only detects light in the visible spectrum and does not detect ultraviolet or infrared light.

Light 25 is preferably focused onto the ambient light sensor 16 by the hole 12 drilled in the LED display 11, as shown in FIG. 3. The location of the hole 12 on the LED display 11 is determined by the location of the ambient light sensor 16 on the circuit board 18. An increase in the ambient light intensity produces a proportional increase in the output current available at the OUT terminal of the ambient light sensor 16. Similarly, a decrease in ambient light intensity produces a proportional decrease in the output current available at the OUT terminal of the ambient light sensor 16.

Load resistor R17 converts the varying output current of the ambient light sensor 16 into a directly proportional varying voltage. Resistor R22 and capacitor C12 form an RC filter network for the voltage converted by the load resistor R17. The RC filter network eliminates rapid changes in the output of the ambient light sensor 16 that is produced by unstable ambient light settings, which, if left unfiltered, could produce annoying and undesirable variations in the LED display's 11 brightness.

The series circuit of the resistor R20, the potentiometer R19, and the resistor R18 is used to set the minimum LED display brightness when there is no ambient light striking the photosensitive top surface of the ambient light sensor 16, a condition that occurs in dimly lit environments or in complete darkness. The resistors R21 and R23 sum the output voltages from the minimum-brightness-adjustment potentiometer R19 and the ambient light sensor 16 and apply the voltage sum to the inverting input (pin 4) of the operational amplifier 22.

As the ambient light striking the photosensitive top surface of the ambient light sensor 16 increases, the operational amplifier 22 amplifies the summed voltages inputted to the operational amplifier's 22 inverting input (pin 4). Operational amplifier's 22 VOUT pin becomes more negative and in turn drives a voltage-follower network including resistors R24, R9, and R10 and power transistor Q1. The signal of the VOUT pin is applied to the base of the power transistor Q1, which causes the power transistor Q1 to conduct between the emitter and the collector. The power transistor Q1's increasing collector voltage is applied directly to the LED display's 11 anodes AN1, AN2, AN3, and AN4, which are schematically shown in FIGS. 2A and 2C. An increase in the anode voltage of the LED display 11 produces an increase in the LED display's 11 brightness. Capacitor C8 filters the anode drive voltage AN1-AN4 and provides a stable feedback voltage to operational amplifier 22. Conversely, a decrease in ambient light striking the photosensitive top surface of the ambient light sensor 16 reverses the process and produces a decrease in LED display's 11 brightness. The light sensor circuit automatically and continuously adjusts the LED intensity up or down as needed to track ambient light levels.

The external brightness adjustment input 20 (pin 2) is also connected to the inverting input (pin 4) of the operational amplifier 22. The external brightness adjustment input 20 enables a user to apply a voltage generated external to the digital panel meter 10, which can completely disable the ambient light sensor's 16 control over the LED display's 11 brightness. Applying a +2.5V or higher signal directly to the external brightness adjustment input 20 will set the LED display's 11 light output to maximum brightness. Connecting the external brightness adjustment input 20 directly to ground GND will reduce the LED display's 11 brightness to zero, i.e., turning the LED display 11 off. The external brightness adjustment input 20 can also be connected to an external voltage source to allow for full manual adjustment of the LED display's 11 brightness. The LED display's 11 brightness will preferably increase from minimum to maximum intensity as the voltage applied to the external brightness adjustment input 20 input is varied from approximately +0.8V up to approximately +2.5V. It is also possible to use different minimum and maximum voltages.

The external brightness adjustment input 20 is normally left open to enable the automatic brightness adjustment mode of LED display 11. While in this mode, ambient light sensor 16 and its associated circuitry will adjust the LED display's 11 brightness to automatically compensate for changes in ambient lighting levels.

The analog-to-digital converter 23, shown in FIG. 2B and employed in a preferred embodiment of the present invention, is commonly referred to as a ‘dual-slope integrating ADC.’ The analog-to-digital converter 23 is preferably located on the surface of the circuit board 18 opposite to the surface of the circuit board 18 to which the LED display 11 is mounted. However, the analog-to-digital converter 23 and the LED display 11 can be located on the same side of the circuit board 18. Dual-slope integrating ADC integrated circuits similar to the analog-to-digital converter 23 have been extensively employed in the design of digital panel instrumentation for over 25 years. The manner of operation, representative applications, circuit design, and component selection of the analog-to-digital converter 23 are clearly described in their respective manufacturers' technical literature. It is also possible to use other suitable analog-to-digital converters or a combination of suitable analog-to-digital converters.

Dual-slope integrating ADC designs similar to the type used in preferred embodiments of the present invention are well known to those skilled in the art. Therefore, an in-depth, detailed description pertaining to the theory and operation of the dual-slope integrating ADC employed in the present invention is not necessary and will not be presented.

The analog-to-digital converter 23 preferably includes integrated circuit U1; capacitors C2, C3, C5, and C6; and resistors R2 and R3. Resistors R12, R13, R15, and R16; calibration potentiometer R14; and integrated circuit U2 preferably form a precision voltage-reference circuit that allows for calibrating the overall accuracy of the analog-to-digital converter 23. Integrated circuit U4, diode D1, and capacitors C1 and C10 form a negative 5V DC supply that enables the analog-to-digital converter 23 to measure dual-polarity signals at its VIN input terminals, a technique that is commonly referred to as ‘bipolar operation’. Resistor R5 and capacitor C4 are used to bypass to ground any high-frequency VIN components that could produce inaccurate and unstable LED display 11 readings. When optional resistor R4 is installed, the combination of the resistors R5 and R4 form a resistor divider for the input signal VIN being measured by the analog-to-digital converter 23, thereby increasing the maximum input signal VIN which can be measured by said ADC.

A DC voltage, or slowly-varying input signal VIN being measured by the analog-to-digital converter 23 is applied to integrated circuit's U1 INHI+ and INLO− terminals. The input signal VIN is integrated by the integrated circuit U1 and converted to a digital representation at a rate of approximately 2.5 times per second. After a conversion cycle is completed, the integrated circuit U1 provides twenty three digital outputs that are connected to the LED display's 11 segment-drive input terminals. The reading displayed by the LED display 11 can correspond to the direct equivalent of the applied input signal VIN. Alternatively, the input signal VIN can be divided by the previously described R5 and R4 divider network in order to achieve a display reading that can represent other physical units of measurement, a technique commonly referred to as ‘engineering scaling.’

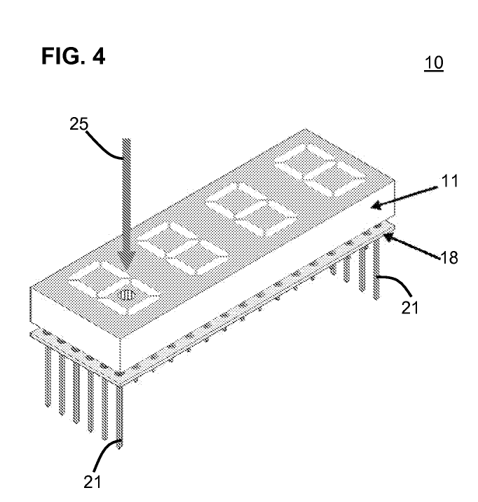

FIGS. 3 and 4 show the digital panel meter 10 according to a preferred embodiment of the present invention. FIG. 3 shows the digital panel meter 10 before the LED display 11 is attached to the circuit board 18. FIG. 4 shows the digital panel meter 10 after the LED display 11 is attached to the circuit board 18. The LED display 11 can be attached to the circuit board 18 using any suitable method.

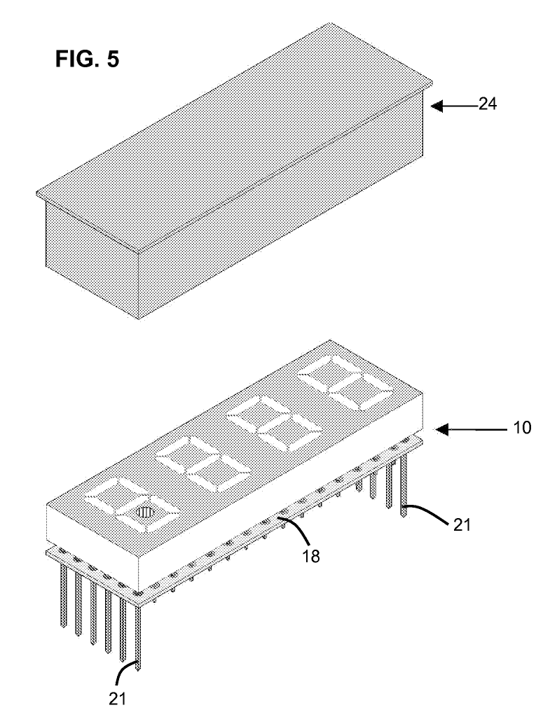

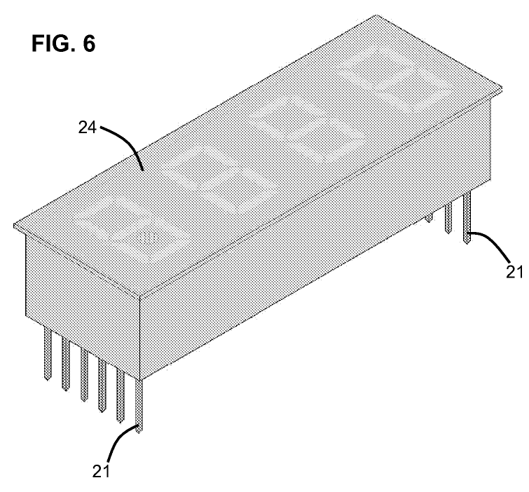

FIGS. 5 and 6 show the digital panel meter 10 and cover 24. FIG. 5 shows the digital panel meter 10 before the cover 24 is attached. FIG. 6 shows the digital panel meter 10 after the cover 24 is attached. The cover 24 can be attached to the digital panel meter 10 using any suitable method. Cover 24 can be made of any suitable material, as long as the light emitted from LED display can be seen by a user.

While the digital panel meter 10 of the preferred embodiments of the present invention is preferably a 3½ digit resolution (i.e., 0 to +/−1999 counts), seven segment, red, digital LED display with three user-selectable decimal points (DP1, DP2, and DP3) and a maximum input signal range (VIN) of +/−1.999 V DC, the daylight readable auto-dimming technique and physical construction can easily be adapted to other digital LED display instruments with higher or lower resolutions and/or input voltage ranges (VIN).

Additionally, preferred embodiments of the present invention need not to be limited to a red seven-segment numeric type LED display. Other LED displays that can be used include alphanumeric (depicts numerals and letters using rectangular-shaped illuminated segments) and dot matrix types (depict numerals and characters using patterns of illuminated dots). Further, while the light-focusing hole 12 drilled through the LED display 11 is advantageous in reducing the physical size of the invention, other ambient light sensors and other LED-mounting configurations can be used with equal effectiveness.

The light emitted by the LED display 11 (i.e., its wavelength or “color”) is not intended to be limited to red light. Any LED color in the visible light spectrum, once LEDs of sufficiently high brightness are available on the market, can also be used.

While a single +5V DC power source is preferably used to supply the necessary electrical current to operate the digital panel meter 10, the +5V DC power could be derived directly or indirectly from other suitable power sources/devices including, but not limited to, AC power mains, storage batteries, solar photovoltaic cells, and other suitable alternative power sources. Further, the absolute amplitude of the referenced +5V DC power source is not critical; however, +5V DC is recognized as an industry standard source of operating power for electronic instrumentation.

While the preferred embodiments of the present invention preferably include a digital panel meter 10 which measures and displays DC voltage, the same techniques can be easily adapted, using well-known electronic circuit configurations, to digitally display other physical parameters including, but not limited to, DC amperage, AC voltage, AC amperage, AC frequency, pressure, vacuum, mass, weight, power, phase angle, temperature, flow rate, velocity, rotational speed, distance, percentages, etc.

Furthermore, the analog-to-digital converter 23 circuitry and construction could be readily replaced by other commonly available microprocessor or microcontroller ICs which include built-in analog-to-digital converter functions and LED display drivers. Various changes to the foregoing described and shown structures would now be evident to those skilled in the art. Accordingly, the particularly disclosed scope of the invention is set forth in the following claims.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

What is claimed is:

1. A daylight-readable digital panel meter comprising:
an LED display having a substrate with a plurality of LED segments, where the substrate includes a hole arranged to allow ambient light to pass through the LED display; and
an automatic adjusting circuit arranged to adjust the LED display in response to a change in the ambient light that passes through the LED display; wherein
the daylight-readable digital panel meter displays a measurement.

2. A daylight-readable digital panel meter of claim 1, wherein the automatic adjusting circuit includes an ambient light sensor that detects the ambient light that passes through the LED display.

3. A daylight-readable digital panel meter of claim 2, wherein the hole focuses the ambient light directly onto the ambient light sensor.

4. A daylight-readable digital panel meter of claim 2, wherein the ambient light sensor has the same or substantially the same response to changes in the ambient light as a human eye would have.

5. A daylight-readable digital panel meter of claim 1, wherein the LED display has a brightness of at least about 100 mcd.

6. A daylight-readable digital panel meter of claim 1, wherein the LED display is driven by at most a DC current of about 200 mA.

7. A daylight-readable digital panel meter of claim 1, wherein the LED display is bright enough to be readable in direct sunlight.

8. A daylight-readable digital panel meter of claim 1, wherein the digital panel meter measures at least one of DC voltage, DC amperage, AC voltage, AC amperage, AC frequency, pressure, vacuum, mass, weight, power, phase angle, temperature, flow rate, velocity, rotational speed, distance, and percentages.

9. A daylight-readable digital panel meter of claim 1, wherein the automatic adjusting circuit continuously adjusts the LED display.

10. A daylight-readable digital panel meter of claim 1, wherein the automatic adjusting circuit dims the LED display.

11. An LED display assembly comprising:
an LED display having a substrate with a plurality of LED segments and having a viewing surface, where the substrate includes a hole for allowing ambient light to pass through the LED display; and
an ambient light sensor mounted below the viewing surface; wherein
the hole is arranged such that at least some of the plurality of LED segments at least partially surround the hole.

12. An LED display assembly of claim 11, further comprising a circuit board and operating electronics mounted to the circuit board.

13. An LED display assembly of claim 12, wherein the ambient light sensor is mounted to the circuit board.

14. An LED display assembly of claim 11, further comprising an automatic adjusting circuit arranged to adjust the LED display in response to a change in ambient light detected by the ambient light sensor.

15. An LED display assembly of claim 14, wherein the automatic adjusting circuit continuously adjusts the LED display.

16. An LED display assembly of claim 14, wherein the automatic adjusting circuit dims the LED display.

17. An LED display assembly of claim 11, wherein the ambient light sensor has the same or substantially the same response to changes in the ambient light as a human eye would have.

18. An LED display assembly of claim 11, wherein the LED display has a brightness of at least about 100 mcd.

19. An LED display assembly of claim 11, wherein the LED display is driven by a DC current of at most about 200 mA.

20. A daylight-readable digital panel meter comprising:
the LED display assembly of claim 11; wherein
the daylight-readable digital panel meter measures at least one of DC voltage, DC amperage, AC voltage, AC amperage, AC frequency, pressure, vacuum, mass, weight, power, phase angle, temperature, flow rate, velocity, rotational speed, distance, and percentages.

21. A daylight-readable digital panel meter according to claim 1, wherein the LED display includes at least two LED digits;
each of the at least two LED digits includes at least four LED segments; and
either the hole is located within one of the at least two LED digits such that the hole is completely surrounded by four LED segments or the hole is located between two of the at least two LED digits such that the hole is partially surrounded by two LED segments.

22. An LED display assembly according to claim 11, wherein the LED display includes at least two LED digits;
each of the at least two LED digits includes at least four LED segments; and
either the hole is located within one of the at least two LED digits such that the hole is completely surrounded by four LED segments or the hole is located between two of the at least two LED digits such that the hole is partially surrounded by two LED segments.
